(19) United States
(12) Patent Application Publication
(10) Pub. No.: US 2015/0107516 A1
(43) Pub. Date: Apr. 23, 2015

(54) PLASMA TREATMENT APPARATUS AND SUBSTRATE TREATMENT SYSTEM

(71) Applicant: CANON ANELVA CORPORATION, Kawasaki-shi (JP)

(72) Inventors: Koji TSUNEKAWA, Kawasaki-shi (JP); Yoshinori NAGAMINE, Kawasaki-shi (JP); Daisuke NAKAJIMA, Kawasaki-shi (JP)

(21) Appl. No.: 14/501,300

(22) Filed: Sep. 30, 2014

Related U.S. Application Data
(63) Continuation of application No. PCT/JP2012/007489, filed on Nov. 21, 2012.

(30) Foreign Application Priority Data
Mar. 30, 2012 (JP) 2012-081176
Apr. 6, 2012 (JP) 2012-087609

(51) Int. Cl. H01J 37/32

(52) U.S. Cl. CPC H01J 37/32899; H01J 37/32743; H01J 37/32788; H01J 37/32458; H01J 37/32651
USPC 118/719

(57) ABSTRACT

In a substrate treatment system including multiple treatment chambers around a substrate transfer chamber, an increase in apparatus floor area due to installation of additional treatment chambers is reduced. A plasma treatment apparatus according to one embodiment of the present invention includes: a treatment chamber; a substrate holder for holding the substrate; plasma generation unit for forming plasma; multiple gate valves for installation and removal of the substrate; a shield for surrounding the plasma formed by the plasma generation unit; and substrate transfer unit for transferring the substrate through the gate valves. The substrate transfer unit is shielded from the plasma by the shield.

### CROSS-REFERENCES TO RELATED APPLICATIONS

This application is a continuation application of International Application No. PCT/JP2012/007489, filed Nov. 21, 2012, which claims the benefit of Japanese Patent Application Nos. 2012-081176 filed Mar. 30, 2012 and 2012-087609, filed Apr. 6, 2012. The contents of the aforementioned applications are incorporated herein by reference in their entireties.

### TECHNICAL FIELD

The present invention relates to a plasma treatment apparatus and a substrate treatment system, and more particularly relates to a plasma treatment apparatus and a substrate treatment system for treating a substrate using plasma.

### BACKGROUND ART

As a mass-production substrate treatment system, there has been known a so-called cluster-type system treatment chambers around the substrate transfer chamber. As for the cluster-type apparatus, replacement or additional installation of the treatment chambers is possible depending on a substrate treatment process.

Along with the recent complicated substrate treatment process, the number of treatment chambers to be provided around the substrate transfer chamber is increasing.

To respond to such additional installation of treatment chambers, there has been known an apparatus in which multiple substrate transfer chambers are connected and the number of treatment chambers that can be installed therearound is increased (Patent Document 1).

### CITATION LIST

### Patent Document

Patent Document 1: Japanese Patent Application Laid-Open No. Hei 3-19252

### SUMMARY OF INVENTION

### Technical Problem

However, with such a configuration, when the treatment chambers are installed around each of the substrate transfer chambers and additional treatment chambers need to be further provided, another substrate transfer chamber always has to be provided. Therefore, an installation area of the substrate treatment system is increased.

To solve the above problem, it is an object of the present invention to reduce an increase in installation area of a substrate treatment system even when additional treatment chambers are provided in the substrate treatment system.

One aspect of the present invention to achieve the above object is a plasma treatment apparatus for treating a substrate using plasma, comprising: a treatment chamber; a substrate holder for holding the substrate provided in the treatment chamber; a plasma generation unit for forming plasma in the treatment chamber; a gate valve for carrying the substrate into and out of the treatment chamber; and a substrate transfer unit, provided in the treatment chamber, for transferring the substrate inside the treatment chamber and performing at least one of installation and removal of the substrate into and from the treatment chamber through gate valve.

The use of the plasma treatment apparatus according to the present invention enables additional treatment chambers to be installed without further providing another substrate transfer chamber in a substrate treatment system including a substrate transfer chamber.

### BRIEF DESCRIPTION OF DRAWINGS

FIG. 1 is a diagram for explaining a plasma treatment apparatus according to a first embodiment.

FIG. 2 is a diagram for explaining a plasma treatment apparatus according to a second embodiment.

FIG. 3 is a diagram for explaining substrate transfer means (transfer robot) according to the first embodiment.

FIG. 4 is a diagram for explaining the substrate transfer means (transfer robot) according to the first embodiment.

FIG. 5 is a diagram for explaining a substrate treatment system according to the first embodiment.

FIG. 6 is a diagram for explaining a substrate removal operation in the plasma treatment apparatus according to the second embodiment.

FIG. 7 is a diagram for explaining the substrate removal operation in the plasma treatment apparatus according to the second embodiment.

FIG. 8 is a diagram for explaining the substrate removal operation in the plasma treatment apparatus according to the second embodiment.

FIG. 9 is a diagram for explaining a plasma treatment apparatus according to a third embodiment.

FIG. 10 is a diagram for explaining a substrate transfer operation in ties plasma treatment apparatus according to the third embodiment.

FIG. 11 is a diagram for explaining the substrate transfer operation in the plasma treatment apparatus according to the third embodiment.

FIG. 12 is a diagram for explaining the substrate transfer operation in the plasma treatment apparatus according to the third embodiment.

FIG. 13 is a diagram for explaining a plasma treatment apparatus according to a fourth embodiment.

FIG. 14 is a diagram for explaining a substrate transfer operation in the plasma treatment apparatus according to the fourth embodiment.

FIG. 15 is a diagram for explaining the substrate transfer operation in the plasma treatment apparatus according to the fourth embodiment.

FIG. 16 is a diagram for explaining the substrate transfer operation in the plasma treatment apparatus according to the fourth embodiment.

FIG. 17 is a diagram for explaining a plasma treatment apparatus according to a fifth embodiment.

FIG. 18 is a diagram for explaining a plasma treatment apparatus according to a sixth embodiment.

FIG. 19 is a diagram for explaining a dummy substrate transfer operation in the plasma treatment apparatus according to the sixth embodiment.

FIG. 20 is a diagram for explaining the dummy substrate transfer operation in the plasma treatment apparatus according to the sixth embodiment.

FIG. 21 is a diagram for explaining the dummy substrate transfer operation in the plasma treatment apparatus according to the sixth embodiment.

FIG. 22 is a diagram for explaining a plasma treatment apparatus according to a seventh embodiment.

FIG. 23 is a diagram for explaining a plasma treatment apparatus according to an eighth embodiment.

FIG. 24 is a diagram for explaining a substrate treatment system according to a ninth embodiment.

FIG. 25 is a diagram for explaining a plasma treatment apparatus according to the ninth embodiment.

FIG. 26 is a diagram for explaining a substrate treatment system according to a tenth embodiment.

FIG. 27 is a diagram for explaining a substrate treatment system according to an eleventh embodiment.

FIG. 28 is a flowchart for explaining a substrate installation operation using the plasma treatment apparatus according to the second embodiment.

FIG. 29 is a flowchart for explaining the substrate installation operation using the plasma treatment apparatus according to the second embodiment.

FIG. 30 is a diagram for explaining one substrate installation operation in the plasma treatment apparatus according to the second embodiment.

FIG. 31 is a diagram for explaining the substrate installation operation in the plasma treatment apparatus according to the second embodiment.

FIG. 32 is a diagram for explaining the substrate installation operation in the plasma treatment apparatus according to the second embodiment.

FIG. 33 is a diagram for explaining a substrate treatment system according to a twelfth embodiment.

FIG. 34 is a diagram for explaining a substrate treatment system according to a thirteenth embodiment.

FIG. 35 is a diagram for explaining a substrate treatment system according to a fourteenth embodiment.

FIG. 36 is a diagram for explaining a substrate treatment system according to a fifteenth embodiment.

FIG. 37 is a diagram for explaining control means according to the second embodiment.

### DESCRIPTION OF EMBODIMENTS

Embodiments of the present invention are described below. In the following description of the drawings, description of overlapping apparatus configurations may be omitted, and reference numerals in the drawings may also be omitted.

### First Embodiment

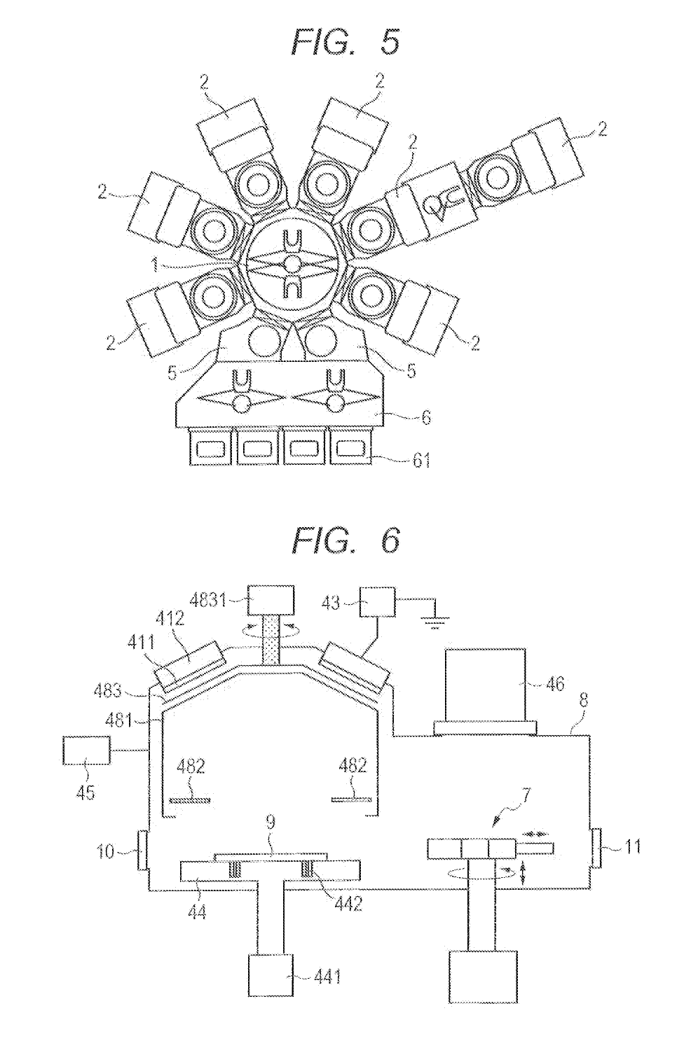

FIG. 5 is a schematic top view showing a configuration of a substrate treatment system according to this embodiment. The substrate treatment system is a cluster-type apparatus, and includes: a substrate transfer chamber 1 disposed in the center; multiple treatment chambers 2 provided around the substrate transfer chamber 1; and two load lock chambers 5. The substrate transfer chamber 1 and the treatment chambers 2 include an unillustrated dedicated or common exhaust system to evacuate the chambers to a predetermined pressure. Also, gate valves are provided at connections between the chambers.

An autoloader 6 is provided on the outside of the load lock chambers 5. The autoloader 6 takes substrates out one by one from an external cassette 61 on the atmosphere side, and houses the substrates in in-lock cassettes inside the load lock chambers 5. Also, a transfer robot is provided in the substrate transfer chamber 1. As the transfer robot, a multijoint robot is used. The transfer robot takes the substrates out one by one from either one of the load lock chambers 5, sends the substrates to the respective treatment chambers 2 for sequential treatment, and then returns the substrates after the last treatment back to either one of the load lock chambers 5.

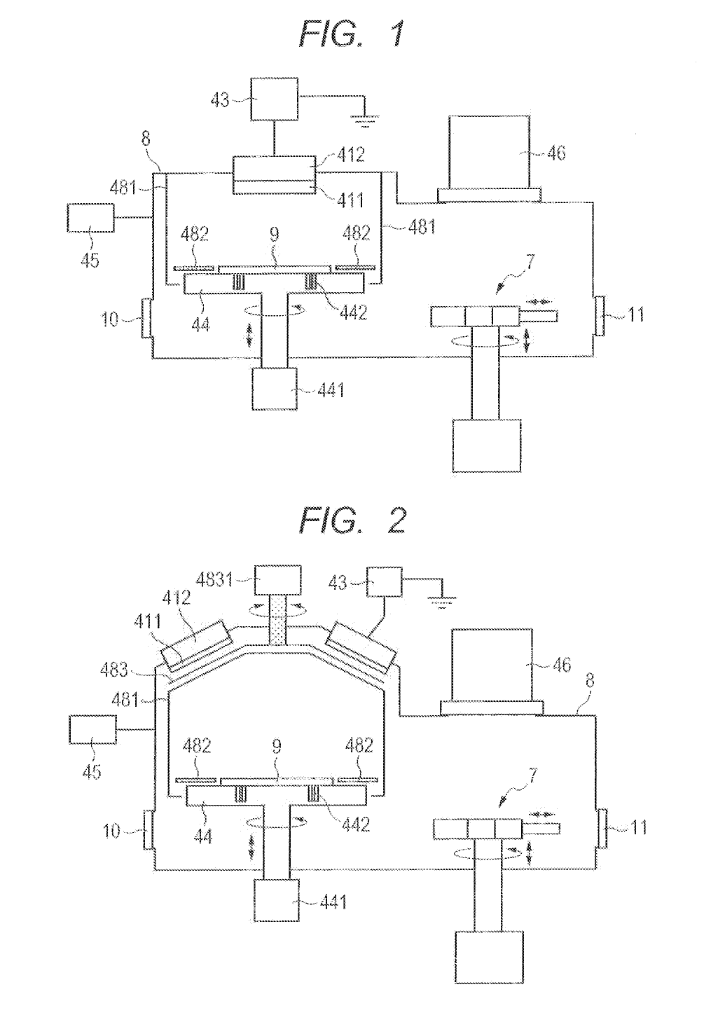

FIG. 1 is a diagram showing a sputtering treatment apparatus, which is one of the treatment chambers, as one embodiment of a plasma treatment apparatus according to the present invention. The plasma treatment apparatus (sputtering apparatus) according to this embodiment includes a treatment chamber 8, an exhaust system 46 to evacuate the treatment chamber 8, and a gas introduction system 45 to introduce gas into the treatment chamber 8. In the treatment chamber 8, provided are: a target 411 provided so as to expose a sputtered surface to the inside of the treatment chamber 8; a target holder 412 for holding the target 411; a discharge power source 43 as plasma generation means for causing sputtering discharge by setting an electric field in a space facing the sputtered surface of the target 411; and a substrate holder 44 to hold a substrate 9 at a predetermined position in the treatment chamber 8 where sputtering particles emitted from the target 411 by the sputtering discharge reach. The substrate holder 44 can be moved up and down along a direction normal to a surface of the substrate 9 or rotated in an in-plane direction of the substrate 9.

The treatment chamber 8 has two gate valves 10 and 11 for connecting to other chambers. The treatment chamber 8 may have at least one gate valve provided therein, and the number of gate valves may be changed according to the number of the other chambers to be connected to the treatment chamber 8. The treatment chamber 8 is a vacuum chamber that is hermetically connected to the substrate transfer chamber 1 through the first gate valve 10 and is hermetically connected to the adjacent treatment chamber through the second gate valve 11. The treatment chamber 8 is electrically grounded. Moreover, the treatment chamber 8 includes an unillustrated opening and closing door, which is opened and closed during periodic maintenance. The opening and closing door is hermetically closed through a sealing member such as an O-ring.

The gas introduction system 45 introduces gas having a high sputtering rate, such as argon, into the treatment chamber 8 at a predetermined flow rate. To be more specific, the gas introduction system 45 mainly includes: a gas cylinder filled with sputtering discharge gas such as argon; a pipe connecting the treatment chamber 8 to the gas cylinder; and a valve and a flow controller, which are provided in the pipe.

The target 411 is a member to be sputtered, including a material of a thin film to be formed on the surface of the substrate 9. The target 411 is attached to the treatment chamber 8 so as to hermetically seal an opening in the upper part of the treatment chamber 8 through an insulator. The discharge power source 43 is configured to apply a negative direct-current voltage of 700 V, for example, to the target 411 with power of about 30 kW through the target holder 412. When the discharge power source 43 is operated in a state where a predetermined gas is introduced by the gas introduction system 45, sputtering discharge is caused near the target 411 to generate plasma of the gas. Accordingly, the target 411 is sputtered by charged particles in the plasma. As the discharge power source 43, a direct-current power source, a high-frequency power source or the like is used.

The substrate holder 44 has the shape of a stage and the substrate 9 can be placed on an upper surface thereof. The substrate holder 44 is configured such that the substrate 9 is placed parallel to the target 411. Note that an unillustrated substrate temperature regulation mechanism may be provided inside the substrate holder 44 to improve the quality of film formation by heating or cooling the substrate 9 before or during film formation. When the sputtering discharge is caused in a state where the substrate 9 is held by the substrate holder 44, sputtering particles emitted from the target 411 reach the surface of the substrate 9, and the sputtering particles pile up to form a thin film.

In the substrate holder 44, multiple pins 442 are provided for passing of the substrate 9. The pins 442 are members fixed to the substrate holder 44 and extended upward. The substrate holder 44 has through-holes into which the pins 442 are inserted. For the pins 442, a drive unit (not shown) is provided to move the pins 442 up and down in the direction normal to the surface of the substrate 9 (or a substrate mounting surface of the substrate holder 44). The up-and-down movement of the pins 442 on which the substrate 9 is placed can switch between a state where the substrate 9 is in contact with the substrate holder 44 and a state where the substrate 9 is separated from the substrate holder 44.

Moreover, inside the treatment chamber 8, a transfer robot 7 is provided as substrate transfer means for transferring the substrate inside the treatment chamber 8 by carrying the substrate 9 into and out of the treatment chamber 8. The transfer robot 7 removes the substrate 9 after treatment from the substrate holder 44, and transfers the substrate to the adjacent treatment chamber through the gate valve 11.

The transfer robot 7 may be capable of at least one of carrying the substrate 9 into the treatment chamber 8 and carrying the substrate 9 out of the treatment chamber 8.

A circular shield 481 is disposed around the substrate holder 44 and the target 411. The shield 481 has its upper side fixed to the ceiling of the treatment chamber 8. Moreover, a peripheral shield 482 is disposed so as to prevent deposition of sputtering particles on the substrate holder 41 except for the surface to be treated of the substrate 9. Each of the shield 481 and the peripheral shield 482 may be one component or may be formed of multiple split components. Alternatively, the shield 481 and the peripheral shield 482 may be integrally formed. In this embodiment, the shield 481 has the circular shape and the upper side thereof is fixed to the ceiling of the treatment chamber 8. However, a structure may be adopted in which the ceiling except for the installation part of the target 411 is covered with another shield and the circular shield 481 is attached to the ceiling shield. Moreover, the ceiling shield and the circular shield 481 may be integrally formed.

The shield 481 can prevent the transfer robot 7 from being exposed to plasma, i.e., can shield the transfer robot 7 from the plasma during treatment of the substrate 9. Thus, the transfer robot 7 can be protected from influences such as heat caused by the plasma. Moreover, the shield 481 can suppress adhesion of the sputtering particles to the transfer robot 7 during treatment of the substrate 9. Accordingly, the shield 481 can reduce dust and the like caused when the transfer robot 7 is driven.

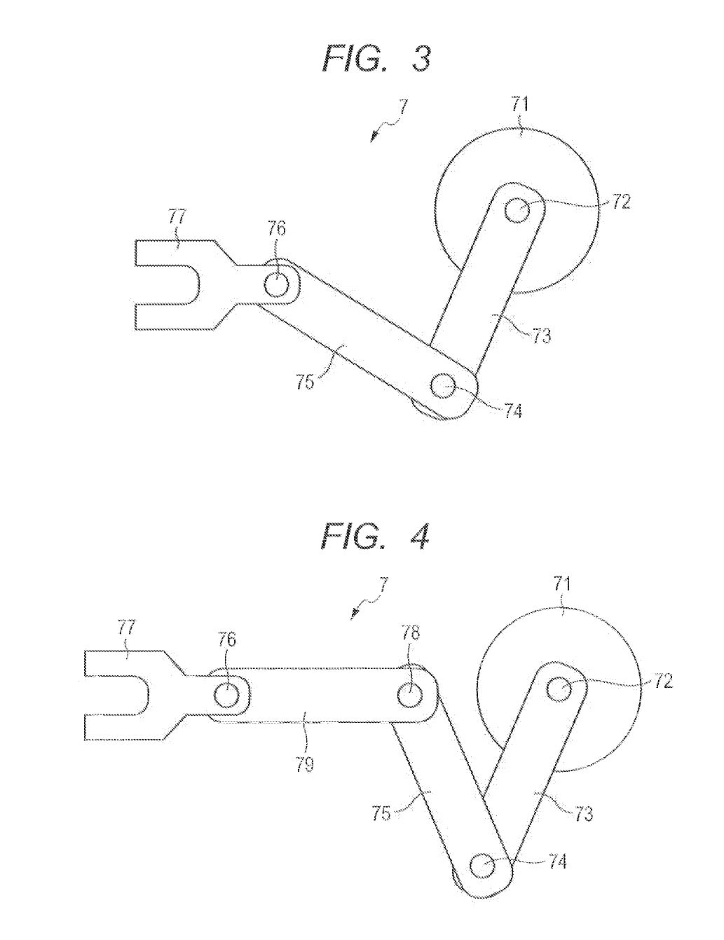

FIG. 3 is a schematic top view showing a configuration of the transfer robot 7 according to this embodiment. The transfer robot 7 includes: a substrate holding part 77 to hold the substrate 9; a first arm 75 connected to the substrate holding part 77 by a connection part 76; a second arm 73 connected to the first arm 75 by a connection part 74; and an arm supporting part 71 connected to the second arm 73 by a connection part 72. The substrate holding part 77, the first arm 75 and the second arm 73 are configured so as to be independently rotatable in a horizontal direction by means of the connection parts 76, 74 and 72, respectively. An end of the first arm 75, which is not connected to the substrate holding part 77, is connected to the second arm 73. Meanwhile, an end of the second arm 73, which is not connected to the first arm 75, is connected to the arm supporting part 71. Thus, the first and second arms 75 and 73 enable the substrate 9 to be freely transferred in the in-plane direction, i.e., horizontal direction.

An unillustrated drive unit is provided in each of the connection parts 76, 74 and 72, and an operation of the drive unit is controlled by unillustrated transfer control means. It is preferable that the substrate holding part 77 has an adsorption part such as an electrostatic adsorption mechanism to stably hold the substrate 9 during transfer.

The transfer robot 7 may further include a third arm 79 or another arm as shown in FIG. 4. When the transfer robot 7 has the third arm 79, the third arm 79 and the substrate holding part 77 are connected by the connection part 76, and the third arm 79 and the first arm 75 are connected by a connection part 78. The third arm 79 is configured so as to be rotatable in the horizontal direction by means of the connection part 78, and an unillustrated drive unit is provided in the connection part 78. The more arms are included, the more finely the transfer of the substrate can be controlled.

In this embodiment, as described above, the transfer robot is provided inside the treatment chamber in the plasma treatment apparatus. Thus, another treatment chamber can be connected, without through the substrate transfer chamber 1, to the treatment chamber 2 connected to the substrate transfer chamber 1. Such a configuration allows for installation of additional treatment chambers 2 without adding a new substrate transfer chamber. Thus, an increase in an installation area of the plasma treatment apparatus is reduced, and a degree of freedom of arrangement can be increased.

Furthermore, in the plasma treatment apparatus according to this embodiment, the multiple treatment chambers can be connected. Thus, the substrate 9 can be quickly transferred to the other treatment chamber without through the substrate transfer chamber 1 after predetermined treatment of the substrate 9. Therefore, in a process in which the transfer time of the substrate 9 can influence final device characteristics, the device characteristics can be improved by reducing the transfer time. Moreover, since the substrate transfer chamber 1 generally exchanges the substrate with the atmosphere through the load lock chambers 5, a degree of vacuum is likely to be lowered. Meanwhile, the use of the plasma treatment apparatus according to this embodiment enables the substrate 9 to be transferred to the adjacent treatment chamber without through the substrate transfer chamber 1. Thus, contamination of the surface of the substrate 9 can be reduced during the transfer.

### Second Embodiment

FIG. 2 is a diagram showing a plasma treatment apparatus (sputtering treatment apparatus) according to this embodiment. In the first embodiment, the target 411 is disposed parallel to the substrate 9. Meanwhile, in this embodiment, multiple targets 411 are provided in a treatment chamber 8, and each of the targets 411 obliquely faces a substrate 9. In FIG. 2, the treatment chamber 8 includes a target shutter 483 and a target shutter drive mechanism 4831, in addition to the configuration shown in FIG. 1. A shield 481 and the target shutter 483 have openings at positions corresponding to the targets. The rotation of the target shutter 483 by the target shutter drive mechanism 4831 can switch between a state where the openings in the target shutter 483 coincide with the directions of the targets 411 and a state where the openings do not coincide with the direct ions of the targets, i.e., between a state where the targets 411 and an internal space of the shield 481 are communicated with each other and a state where the targets and the internal space are not communicated with each other. Such a configuration makes it possible to select one of the targets 411 to be used for sputtering or to protect the targets 411 during cleaning of the treatment chamber 8.

The other configuration and effects achieved by the configuration are the same as those in the first embodiment.

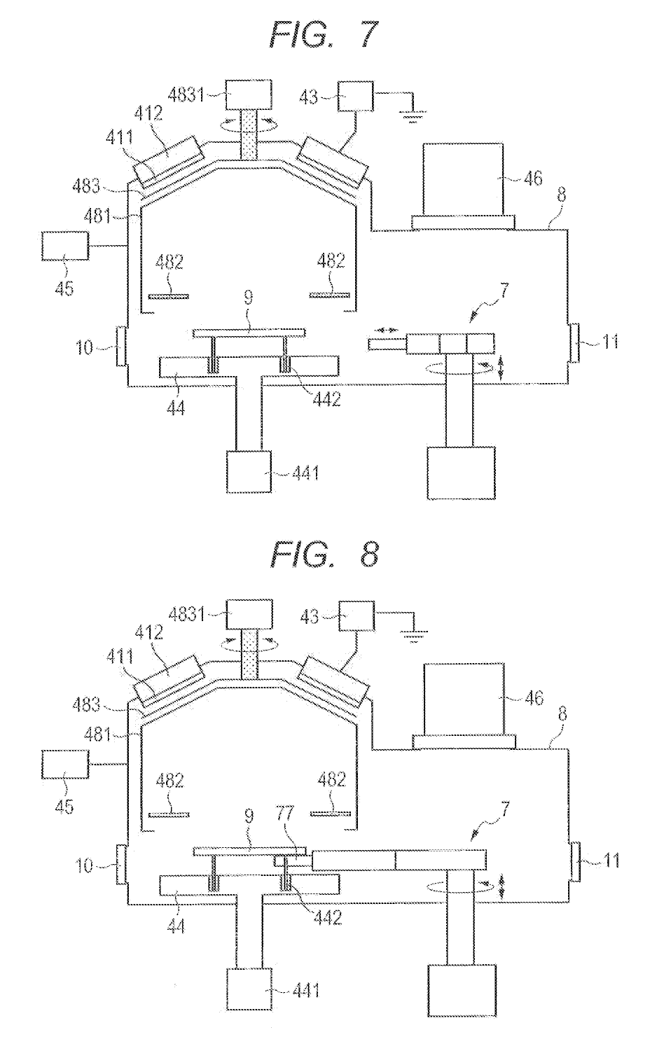

FIGS. 6 to 8 are diagrams explaining an operation of removing the substrate 9 using the plasma treatment apparatus according to this embodiment. First, as shown in FIG. 6, a substrate holder drive unit 441 lowers the substrate holder 44 having the substrate 9 placed thereon. Then, as shown in FIG. 7, as the pins 442 are lifted, the substrate 9 is separated from the surface of the substrate holder 44. Thereafter, as shown in FIG. 8, the substrate holding part 77 of the transfer robot 7 moves to the backside of the substrate 9 to hold the substrate 9, and the transfer robot 7 transfers the substrate 9 to the adjacent treatment chamber through the gate valve 11.

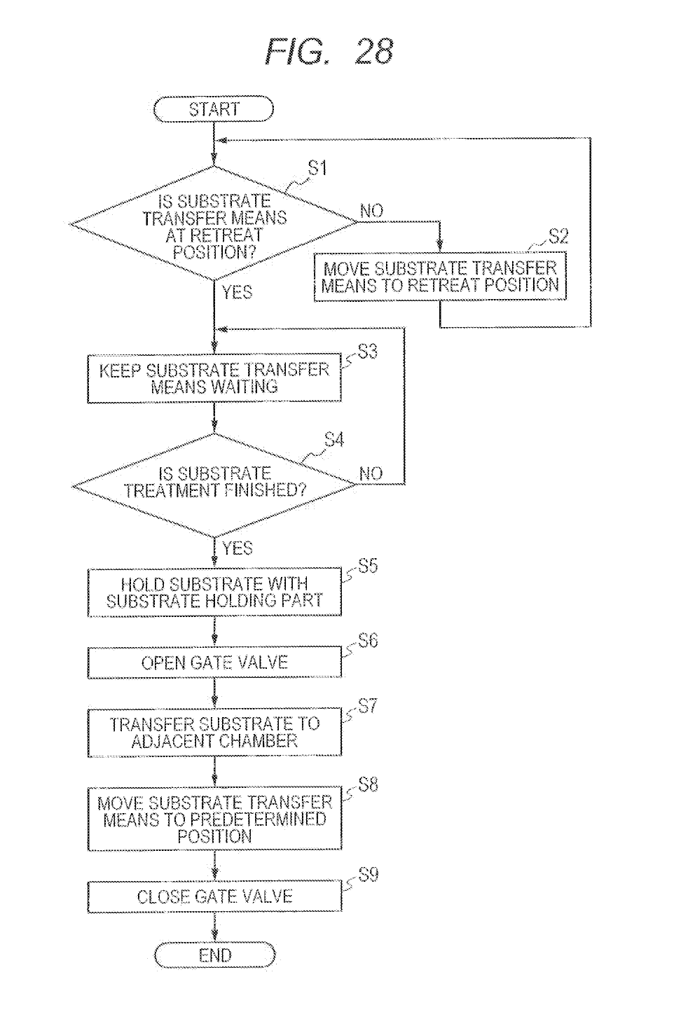

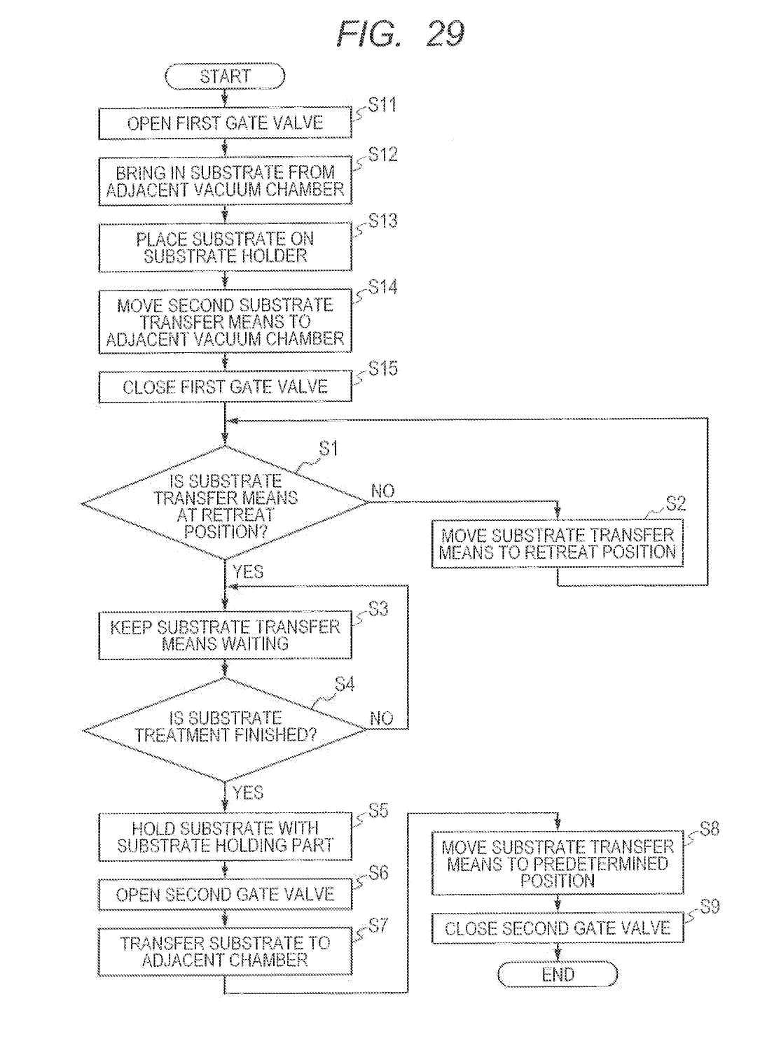

FIG. 28 is a flowchart illustrating the removal operation using the plasma treatment apparatus according to this embodiment. This flowchart shows the operation when using the apparatus configuration shown in FIGS. 6 to 8. First, the transfer control means determines whether or not the substrate transfer means (transfer robot 7) is placed at a position (retreat position) not exposed to plasma, before treatment of the substrate 9 is started (Step S1). The retreat position means a position where the transfer robot 7 is shielded from the plasma by the shield 481 during treatment of the substrate 9. When the transfer robot 7 is placed at a position exposed to the plasma, the transfer control means moves the transfer robot 7 to the retreat position by driving the arm supporting part 71, the first arm 72 and the second arm 73 (Step S2). Thereafter, it is determined again in Step S1 whether or not the transfer robot 7 is placed at the retreat position. When the transfer robot 7 is placed at the position (retreat position) not exposed to the plasma, the transfer robot stands by while maintaining its state (Step S3).

Subsequently, it is determined whether or not plasma treatment of the substrate 9 is finished (Step S4). After the plasma treatment, the substrate 9 is transferred using the transfer robot 7. To be more specific, the transfer control means drives the arm supporting part 71, the first arm 75 and the second arm 73 to move the substrate holding part 77 to the backside of the substrate 9, and causes the substrate holding part 77 to hold the substrate 9 (Step S5). Then, the second gate valve 11 is opened (Step S6). Thereafter, the arm supporting part 71, the first arm 75 and the second arm 73 are driven again to move the substrate 9 from the substrate holder 44, and the substrate 9 is transferred to the adjacent treatment chamber through the second gate valve 11. Accordingly, the substrate 9 is carried out of the treatment chamber 8 (Step S7). Last, the transfer robot 7 is returned to a predetermined position (Step S8), and then the second gate valve 11 is closed (Step S9).

By performing such operations, the transfer robot 7 is prevented from being exposed to the plasma during the treatment of the substrate 9. Thus, adhesion of a deposited material to the transfer robot 7 and damage thereto by the plasma can be prevented.

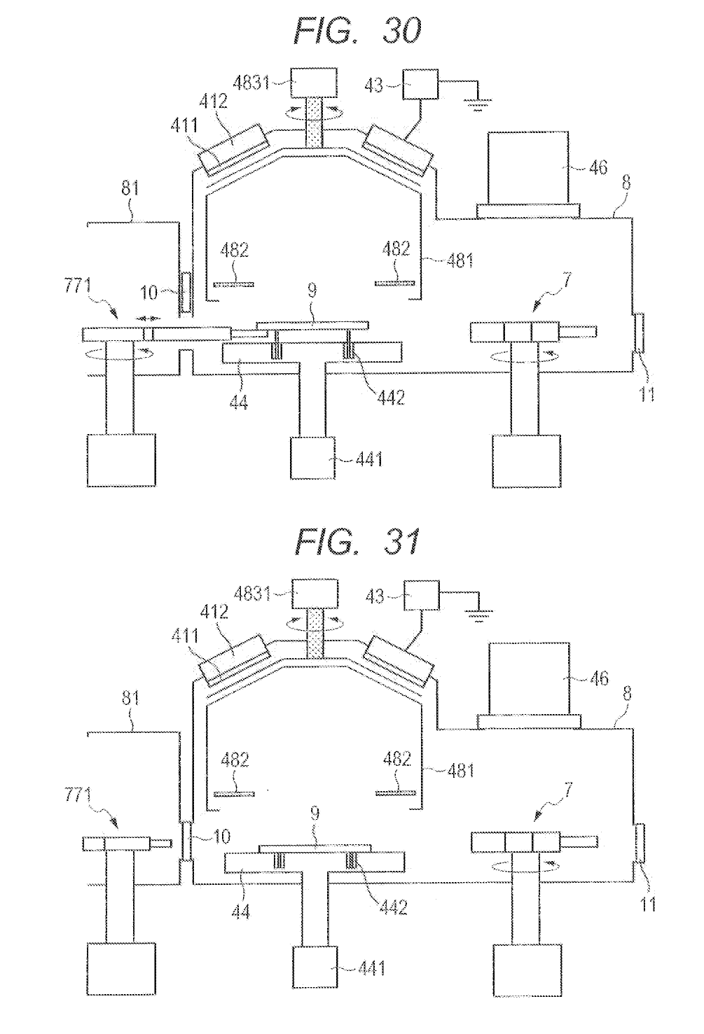

FIGS. 30 to 32 are diagrams explaining an operation of installing the substrate 9 using the plasma treatment apparatus according to this embodiment. In FIGS. 30 to 32, another plasma treatment apparatus (second plasma treatment apparatus) according to this embodiment is further connected to the first gate valve 10 in the plasma treatment apparatus (first plasma treatment apparatus) according to this embodiment. First, as shown in FIG. 30, the substrate holder drive unit 441 in the first plasma treatment apparatus lowers the substrate holder 44, and the pins 442 are lifted at the same time. Then, second substrate transfer means (second transfer robot 771) in the second plasma treatment apparatus carries the substrate 9 out of a vacuum chamber 81 in the second plasma treatment apparatus, and places the substrate 9 on the lifted pins 442. Thereafter, as shown in FIG. 31, the pins 442 are lowered to place the substrate 9 on the surface of the substrate holder 44. Subsequently, as shown in FIG. 32, the substrate holder drive unit 441 lifts the substrate holder 44 having the substrate 9 placed thereon, and holds the substrate holder in a space inside the shield 481.

FIG. 29 is a flowchart illustrating the installation operation using the plasma treatment apparatus according to this embodiment. This flowchart shows the operation when using the apparatus configuration shown in FIGS. 30 to 32. First, the first gate valve 10 is opened to set a state where the substrate can be transferred between the treatment chamber 8 and the vacuum chamber 81 (Step S11). Next, the second transfer robot 771 carries the substrate 9 into the treatment chamber 8 from the vacuum chamber 81 (Step S12). Then, the substrate 9 is placed on the substrate holder 44 (Step S13), and the second transfer robot 771 is moved to the vacuum chamber 81 from the treatment chamber 8 (Step S14). More specifically, by evacuating the second transfer robot 771 from the substrate holder 44 and moving the second transfer robot to the outside of a substrate treatment space P, membrane adhesion to the second transfer robot 771 or the like is prevented from occurring during treatment of the substrate 9. After the second transfer robot 771 is moved to the vacuum chamber 81, the first gate valve 10 is closed (Step S15).

Subsequently, after the substrate 9 is treated by the same operation as that shown in the flowchart or FIG. 28, the substrate 9 is carried to the next treatment chamber (Steps S1 to S9).

Note that the operations by the second transfer robot 771 and the retreat determination and operations by the transfer robot 7 may not be performed in the order shown in FIG. 29. Specifically, the second transfer robot 771 may transfer the substrate 9 from the vacuum chamber 81 (Steps S12 to S14) after the retreat determination and operations by the transfer robot 7 are performed first (Steps S1 and S2). Alternatively, the operations by the transfer robot 7 and the second transfer robot 771 may be performed at the same time.

The transfer control means according to this embodiment includes a general computer and various drivers, for example. FIG. 37 is a diagram showing a configuration of transfer control means 300 according to this embodiment. The transfer control means 300 includes an input unit 300b, a storage unit 300c storing programs and data, a processor 300d and an output unit 300e, and controls the plasma treatment apparatus according to this embodiment. The transfer control means 300 can control the operations of the plasma treatment apparatus by the processor 300d reading and executing a control program stored in the storage unit 300c. In other words, the plasma treatment apparatus can perform the operations illustrated in the flowcharts shown in FIGS. 28 and 29 under the control of the transfer control means 300. Note that the transfer control means 300 may be provided separately from the plasma treatment apparatus or may be included in the plasma treatment apparatus. The transfer control means 300 can detect a treatment status of the substrate 9 and operation statuses of the other components in the apparatus configuration, such as the substrate holder 44 and the pins 442, besides the transfer robot 7, and can control the operations of the transfer robot 7 based on the result of the detection. Accordingly, the transfer robot 7 can be operated according to the operations of such constituent components. Alternatively, the transfer control means 300 may control the operations of the constituent components.

### Third Embodiment

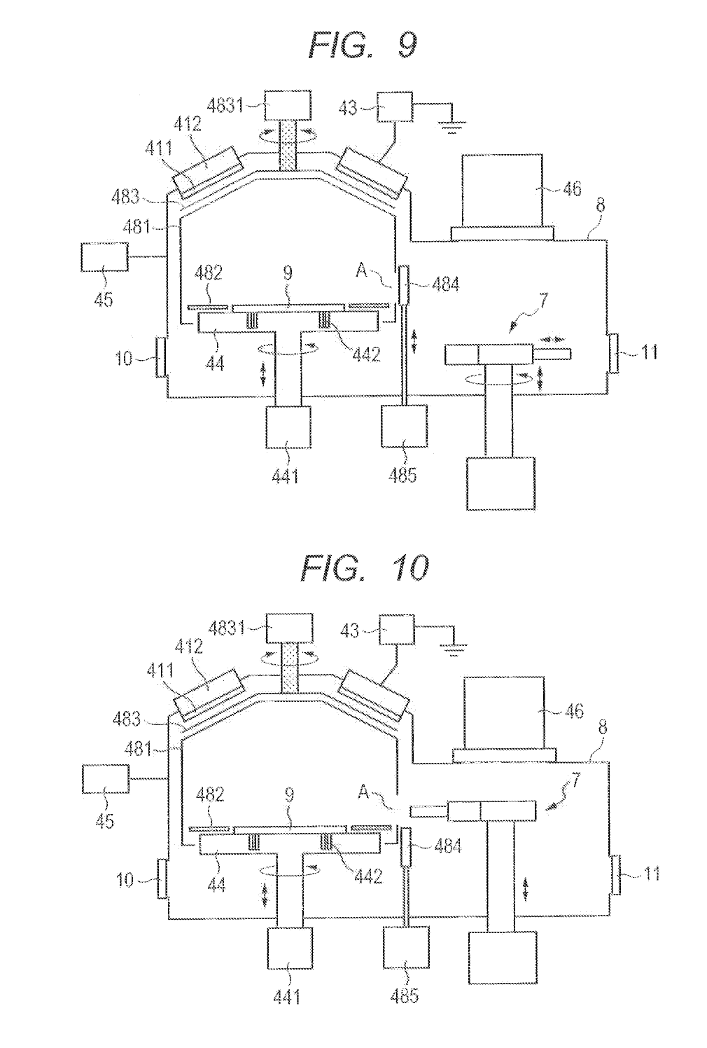

FIG. 9 is a diagram showing a plasma treatment apparatus (sputtering treatment apparatus) according to this embodiment. In this embodiment, a shield 481 has an opening A at a position lateral to a substrate holder 44, and an opening shutter 484 is presided so as to seal the opening A. The opening shutter 484 can be moved up and down by an opening shutter drive unit 485.

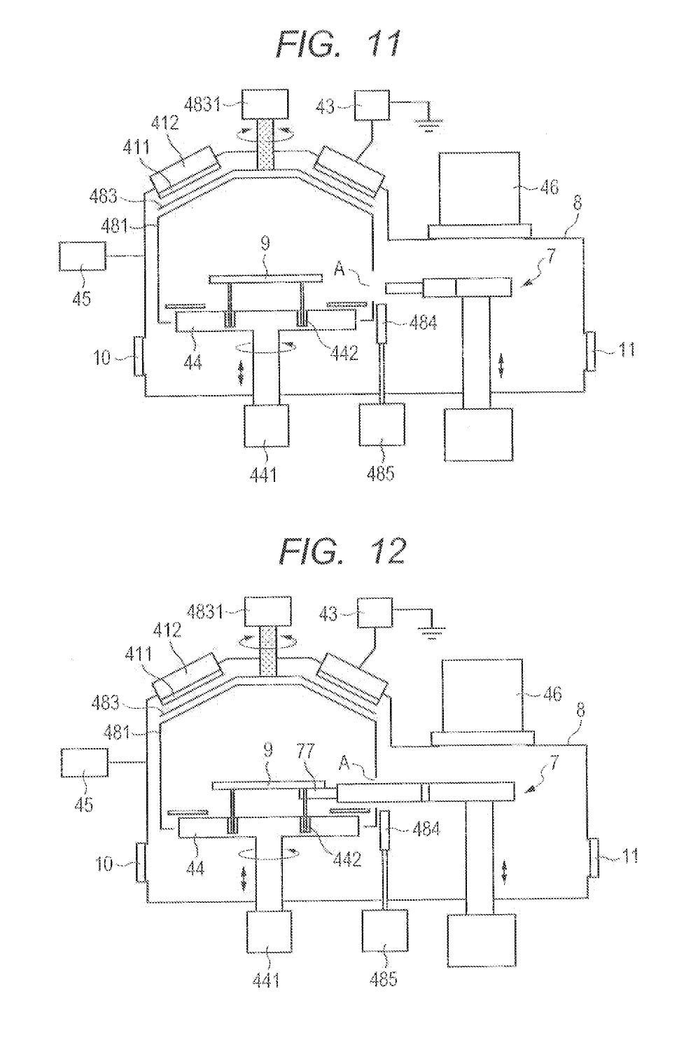

FIGS. 10 to 12 are diagrams explaining an operation of transferring a substrate 9 using the plasma treatment apparatus according to this embodiment. First, as shown in FIG. 10, the opening shutter drive unit 485 lowers the opening shutter 484 to open the opening A in the shield 481. Next, as shown in FIG. 11, as the pins 142 are lifted, the substrate 9 is separated from the surface of the substrate holder 44. Then, as shown in FIG. 12, the substrate holding part 77 of the transfer robot 7 is moved, to the backside of the substrate 9, and the transfer robot 7 transfers the substrate 9 to the adjacent treatment chamber through the gate valve 11.

Note that the opening 7 in the shield 481 may be opened by the opening shutter drive unit 485 not only lowering but also lifting or horizontally moving the opening shutter 484.

### Fourth Embodiment

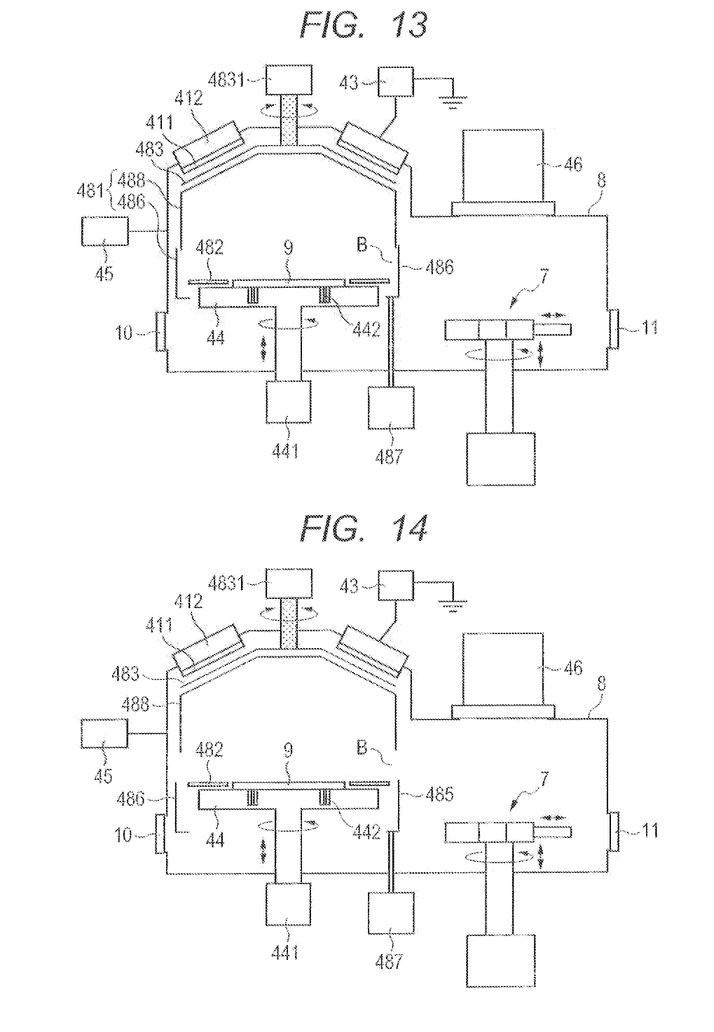

FIG. 13 is a diagram showing a plasma treatment apparatus (sputtering treatment apparatus) according to this embodiment. In this embodiment, a shield 481 surrounding a substrate holder 44 includes a circular upper shield 488 and a circular lower shield 486. The lower shield 486 is connected to a lower shield drive unit 487 which enables up-and-down movement of the lower shield 486. When the lower shield 486 is moved downward, an opening B is formed between the upper shield 488 and the lower shield 486.

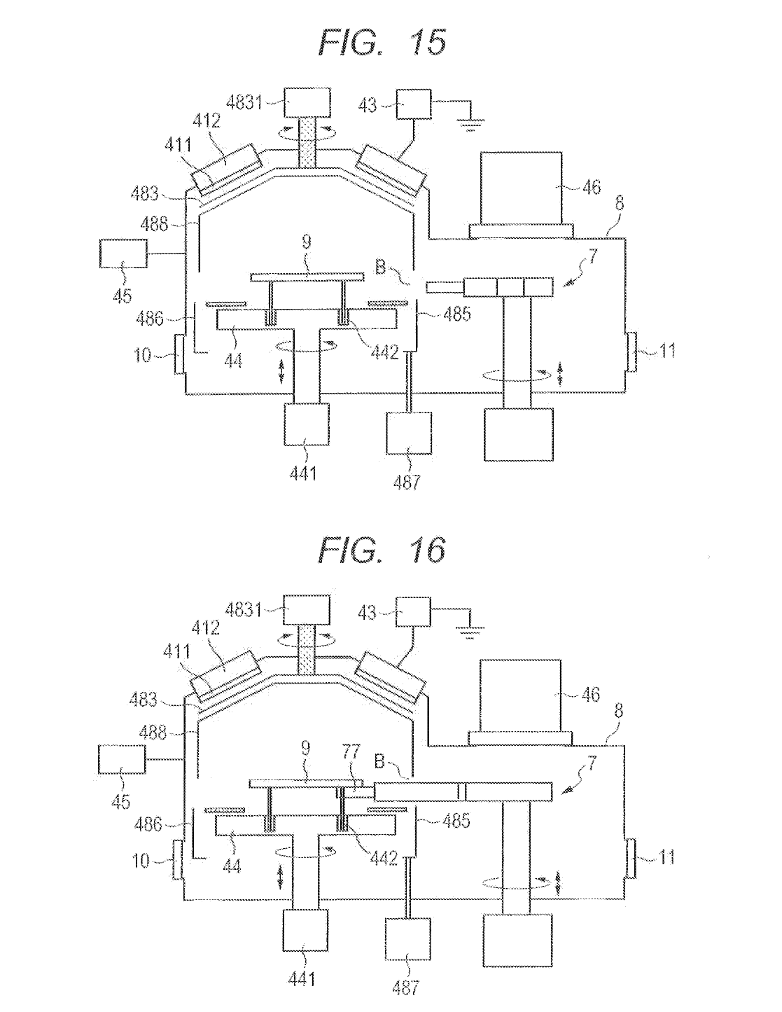

FIGS. 14 to 16 are diagrams explaining an operation of transferring a substrate 9 using the plasma treatment apparatus according to this embodiment. First, as shown in FIG. 14, by the lower shield drive unit 487 lowering the lower shield 486, the upper shield 488 and the lower shield 486 are separated from each other to open the sides lateral to the substrate holder 44, i.e., to form the opening B. Next, as shown in FIG. 15, as the pins 442 are lifted, the substrate 9 is separated from the substrate holder 44. Then, as shown in FIG. 16, the substrate 9 is held by the substrate holding part 77 of the transfer robot 7, and the transfer robot 7 transfers the substrate 9 to the adjacent treatment chamber through the gate valve 11.

Note that, although the lower shield 486 is moved up and down by the lower shield drive unit 487 in this embodiment, the position of the lower shield 486 may be fixed and the upper shield 488 may be moved up and down to create a transfer space for the substrate 9, i.e., the opening B. Alternatively, both, of the upper and tower shields 488 and 486 may be operated to create the transfer space for the substrate 9.

### Fifth Embodiment

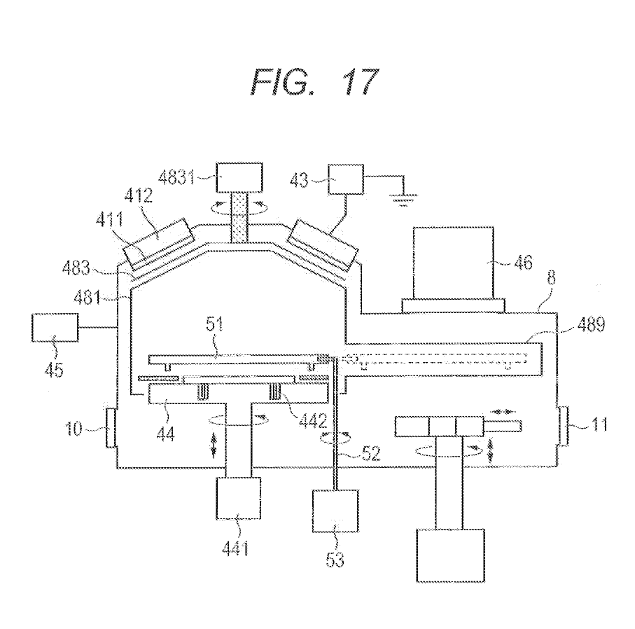

FIG. 17 is a diagram showing a plasma treatment apparatus (sputtering treatment apparatus) according to 51 is provided in a treatment chamber 8, which can shield a substrate holder 44 and a substrate 9 from a target 411. The substrate shutter 51 is configured so as to be rotatable by means of a supporting unit 52 and a drive unit 53. Also, a shield 481 has a storage part 489 on the side. During sputtering film formation on the substrate 9, the substrate 51 is stored in the storage part 489. The substrate shutter 51 is used for conditioning or the like after maintenance is performed by opening the inside of the treatment chamber 8 to the atmosphere, for example. To be more specific, when removing impurities on the surface of the target 411, which adhere thereto by opening to the atmosphere, by sputtering, unnecessary film deposition on the substrate holder 44 can be suppressed by rotating the substrate shutter 51 to a position covering the substrate holder 44.

### Sixth Embodiment

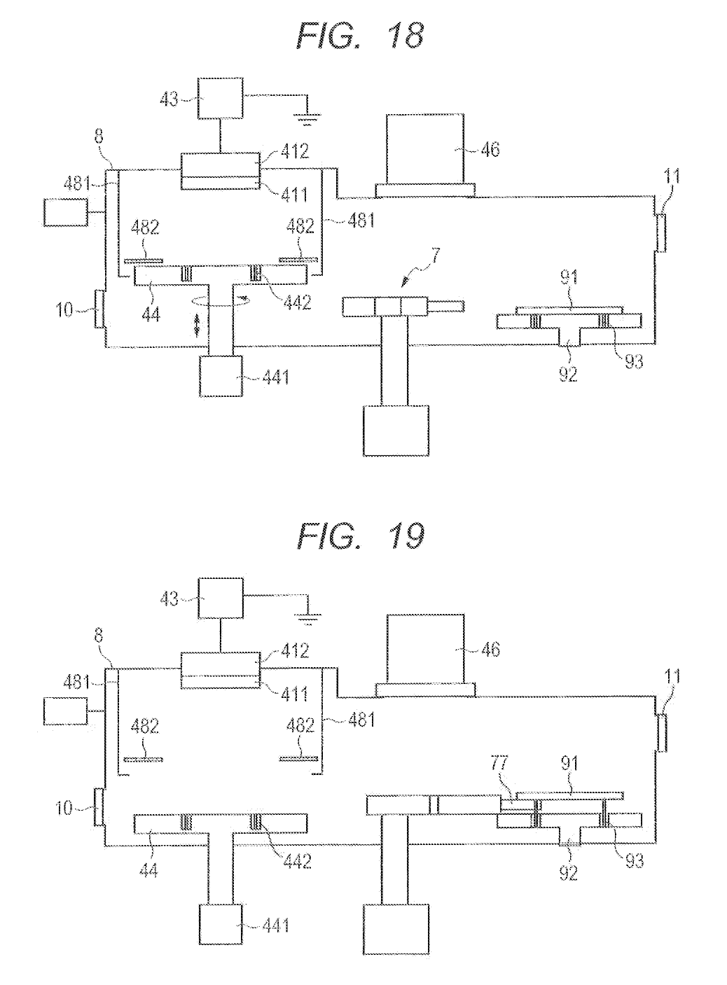

FIG. 18 is a diagram showing a plasma treatment apparatus (sputtering treatment apparatus) according to this embodiment. In this embodiment, a dummy substrate 91 and a dummy substrate holder 92 are provided in a treatment chamber 8. The dummy substrate holder 92 has pins 93 therein. As the pins 93 are moved upward to lift the dummy substrate 91, the dummy substrate 91 can be separated from the dummy substrate holder 92. For the pins 93, an unillustrated drive unit is provided to move the pins 93 up and down. A transfer robot 7 according to this embodiment is configured to be able to not only carry a substrate 9 into and out of the treatment chamber 8 through a gate valve 11 but also move the dummy substrate 91 inside the treatment chamber 8.

While the conditioning inside the treatment chamber 8 is performed using the substrate shutter 51 in the fifth embodiment, such conditioning is performed using the dummy substrate 91 in this embodiment.

According to this embodiment, in addition to the effect achieved in the first embodiment shown in FIG. 1, one transfer robot 7 can perform both of the carrying of the substrate 9 into and out of the treatment chamber 8 and the movement of the dummy substrate 91 inside the treatment chamber 8. Thus, also when adopting the configuration including the dummy substrate, the apparatus can be reduced in size and manufacturing costs of the apparatus can be reduced.

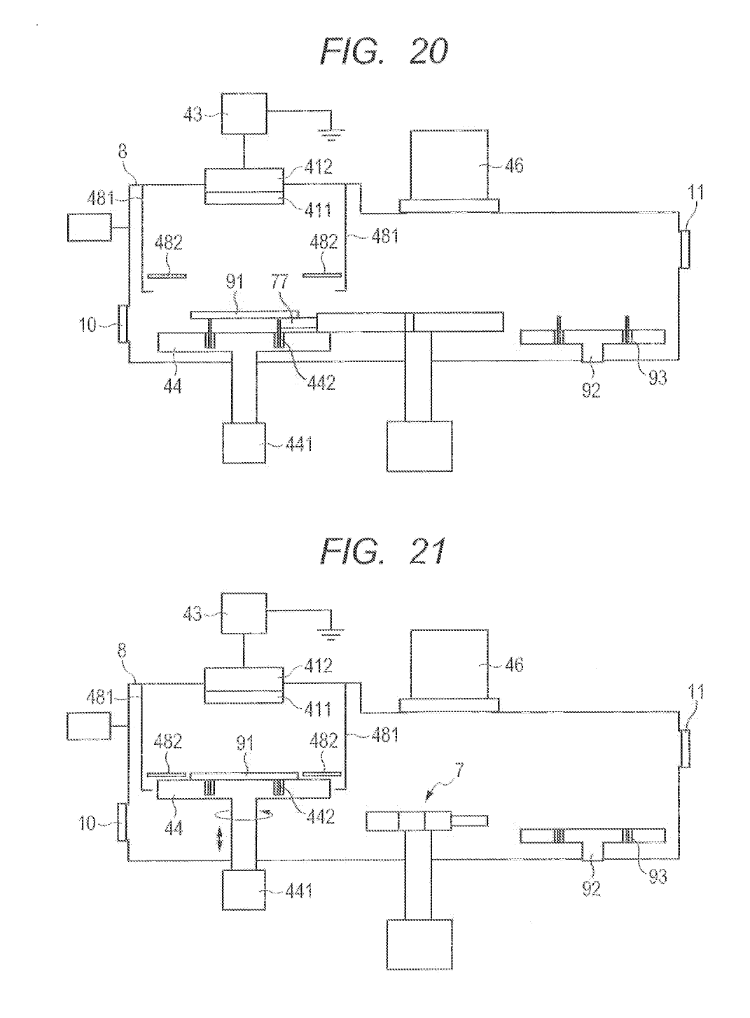

FIGS. 19 to 21 are diagrams explaining an operation of moving the dummy substrate 91 using the plasma treatment apparatus according to this embodiment. First, as shown in FIG. 19, in a state where the substrate 9 is not placed on the substrate holder 44, the substrate holder drive unit 441 lowers the substrate holder 44. Then, by lifting the pins 93, the dummy substrate 91 is separated from the dummy substrate holder 92. Thereafter, the substrate holding part 77 of the transfer robot 7 is moved to the backside of the dummy substrate 91 to hold the dummy substrate 91. Next, as shown in FIG. 20, the pins 442 in the substrate holder 44 are lifted, and the transfer robot 7 is moved to place the dummy substrate 91 on the pins 442. Thereafter, as shown in FIG. 21, the pins 442 are lowered and the dummy substrate 91 is placed on the substrate holder 44. Furthermore, the substrate holder 44 is lifted to a predetermined position for predetermined conditioning. By using the dummy substrate 91 for conditioning, a portion of the substrate holder 44 where the dummy substrate 91 is placed is covered up. Thus, no sputtering particles enter and adhere to the portion. Thus, adhesion of the sputtering particles to the substrate mounting surface of the substrate holder 44 can be suppressed. As a result, generation of particles can be suppressed during replacement of the substrate 9, or the like.

### Seventh Embodiment

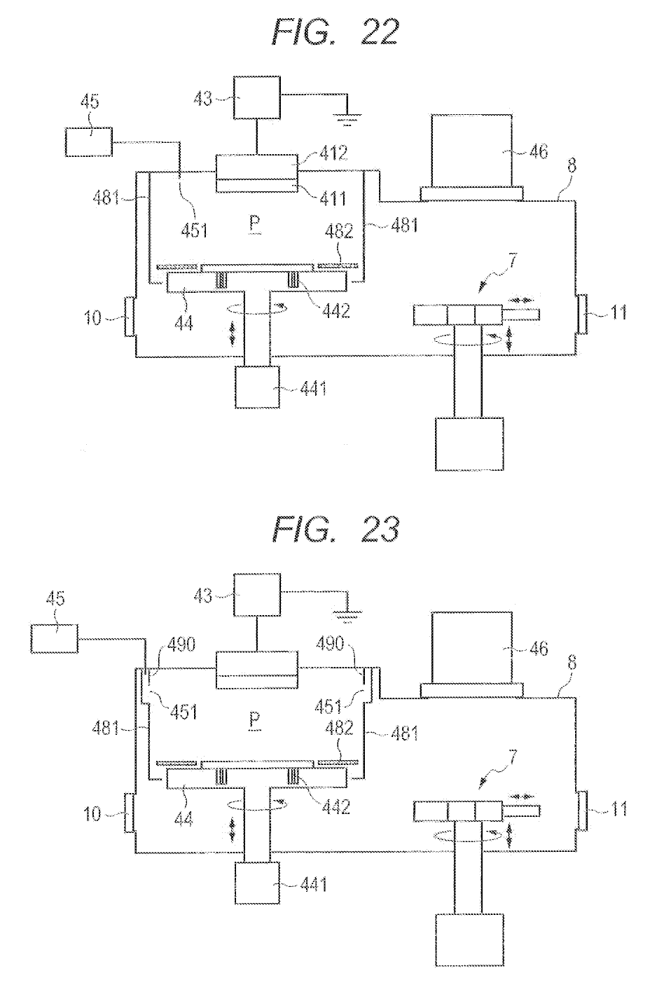

FIG. 22 is a diagram showing a plasma treatment apparatus (sputtering treatment apparatus) according to this embodiment. In this embodiment, a gas introduction part 451 from a gas introduction system 45 for introducing gas into a treatment chamber 8 is provided in a substrate treatment space P surrounded by a shield 481. A transfer robot 7 has a number of drive units, and thus is likely to generate dust during operation. Therefore, the dust may lower the degree of vacuum inside the treatment chamber 8. However, in this embodiment, the gas introduction part 451 provided in the substrate treatment space P causes a pressure gradient between the substrate treatment space P and an external space (i.e., the pressure in the substrate treatment space P becomes larger than that in the external space). Accordingly, intrusion of the dust into the substrate treatment space P can be reduced. Note that, in the present invention, the substrate treatment space P means a space formed by the shield to surround plasma during treatment of the substrate 9.

### Eighth Embodiment

FIG. 23 is a diagram showing a plasma treatment apparatus (sputtering treatment apparatus) according to this embodiment. In this embodiment, an upper part of a shield 481 (i.e., a portion closer to the ceiling of the treatment chamber 8) has a diameter larger than that of a lower part thereof. On the inside of the upper part, a circular sub-shield 490 is provided. A gas introduction part 451 is provided between the shield 481 and the sub-shield 490, and substantially all the gas introduced into the treatment chamber 8 flows between the shield 481 and the sub-shield 490 to be introduced into a substrate treatment space P. More specifically, in this embodiment, the substrate treatment space P is formed by the shield 481 and the sub-shield 490. In such a case, a gap formed by the shield 481 and the sub-shield 490 substantially serves as the gas introduction part 451. With such a configuration, the gas introduced into the treatment chamber 8 is diffused in a circumferential direction of the circular gap, i.e., in a substrate in-plane direction by the gap formed by the shield 481 and the sub-shield 490. Thus, the gas can be introduced more evenly into the substrate treatment space P.

### Ninth Embodiment

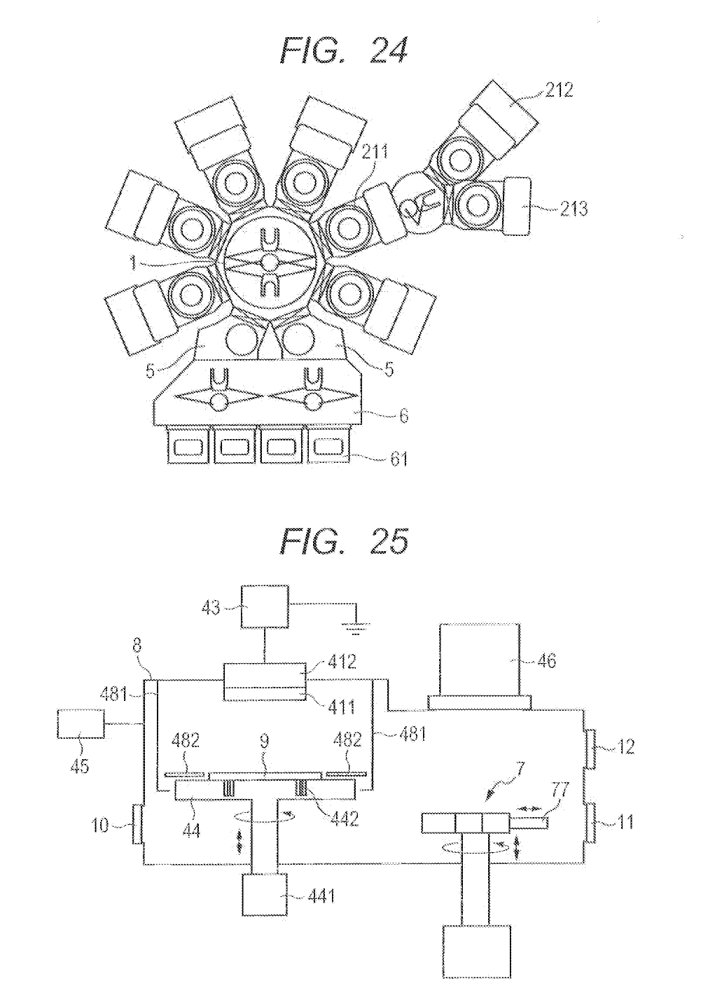

FIG. 24 is a schematic top view of a substrate treatment system according to this embodiment. In this embodiment, a plasma treatment apparatus 211 according to the present invention is hermetically connected to a substrate transfer chamber 1. In the plasma treatment apparatus 211, other treatment chambers 212 and 213 are connected to a gate valve on the opposite side to the substrate transfer chamber 1. Examples of treatment to be performed in the respective treatment chambers include: deposition treatment using sputtering in the plasma treatment apparatus 211; oxidation treatment of the substrate 9 in the treatment chamber 212; and etching treatment of the substrate 9 in the treatment chamber 213. The treatment chambers 212 and 213 are disposed at different heights and also disposed so as to partially overlap with each other in a horizontal direction. Thus, a floor area of the substrate treatment system is reduced.

FIG. 25 is a diagram showing the plasma treatment apparatus 211 included in the substrate treatment system according to this embodiment. As a difference from the first embodiment shown in FIG. 1, the plasma treatment apparatus 211 according to this embodiment includes a third gate valve 12 hermetically connected to the treatment chamber 213, in addition to the second gate valve 11 hermetically connected to the treatment chamber 212. The second and third gate valves 11 and 12 have different heights. During transfer of the substrate 9, a height position of a substrate holding part 77 is adjusted by moving up and down a supporting rod of the transfer robot 7. This mates it possible to select between the gate valves 11 and 12 to carry in and out the substrate 9.

### Tenth Embodiment

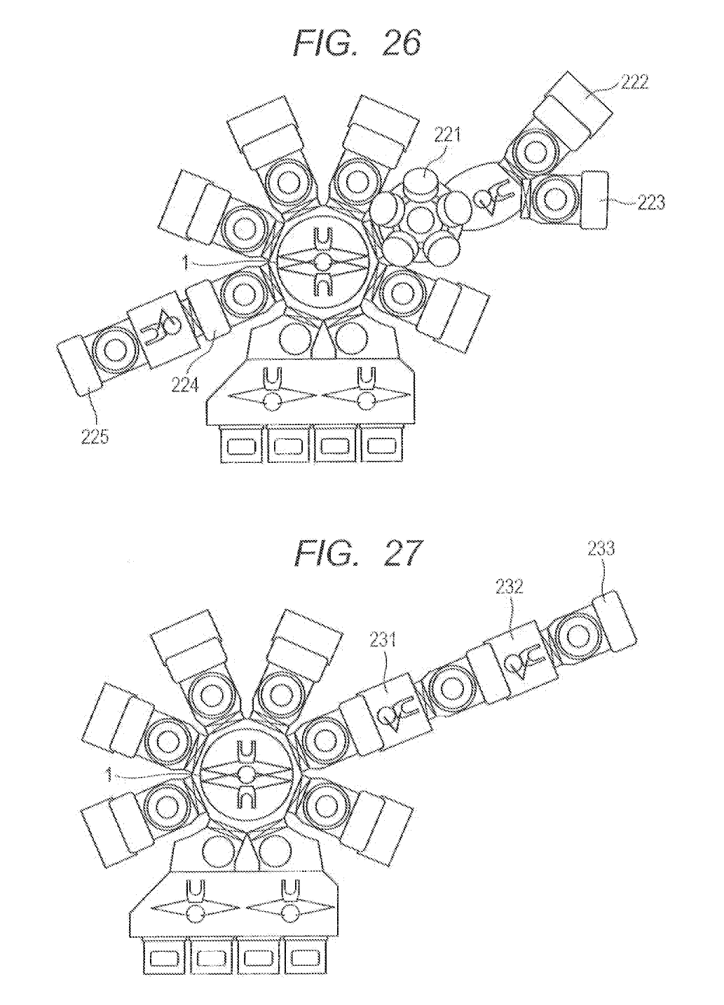

FIG. 26 is a schematic top view of a substrate treatment system according to this embodiment. In this embodiment, a plasma treatment apparatus 221 according to the present invention is connected to a substrate transfer chamber 1, and a plasma treatment apparatus 225 according to the present invention is connected to another treatment chamber 224. In the ninth embodiment shown in FIG. 24, the plasma treatment apparatus 211 according to the present invention is connected to the substrate transfer chamber 1. On the other hand, in this embodiment, the treatment chamber 224 is connected to the substrate transfer chamber 1, and the plasma treatment apparatus 225 according to the present invention is connected to the treatment chamber 224. Moreover, the plasma treatment apparatus (deposition treatment apparatus) 221 including multiple targets according to the present invention is connected to the substrate transfer chamber 1, and other treatment chambers 222 and 223 are connected to the deposition treatment apparatus 221.

Examples of treatment to be performed in the respective treatment chambers in this embodiment include heat treatment in the treatment chamber 224 and plasma oxidation treatment in the plasma treatment apparatus 225. The heat treatment in the treatment chamber 221 may be performed by flowing high-temperature gas to the backside of the substrate by using a substrate holder including an electrostatic adsorption mechanism, for example. In the plasma oxidation treatment in the plasma treatment apparatus 225, oxidation treatment of the substrate is performed by introducing an oxygen-containing gas into the treatment chamber and thus forming plasma. Alternatively, the electrostatic adsorption mechanism described above may be provided in the substrate holder in the deposition treatment apparatus 221 to perform heating and cooling. Furthermore, a configuration may be adopted in which the treatment chamber 222 is similarly used as a deposition treatment chamber and the electrostatic adsorption mechanism is provided in the substrate holder, thereby enabling heating and cooling to be performed in both of the deposition treatment apparatus 221 and the treatment chamber 222. Such a configuration enables heating and cooling to be quickly performed after deposition treatment of the substrate.

### Eleventh Embodiment

FIG. 27 is a schematic top view of a substrate treatment system according to this embodiment. In this embodiment, a plasma treatment apparatus 231 according to the present invention is connected to a substrate transfer chamber 1. Also, a plasma treatment apparatus 232 according to the present invention is further connected to the plasma treatment apparatus 231, and another treatment chamber 233 is connected to the plasma treatment apparatus 232. In this way, the plasma treatment apparatuses 231 and 232 according to the present invention, can be serially connected (i.e., connected in series). Moreover, three or more plasma treatment apparatuses according to the present invention may be connected in series.

The configuration according to this embodiment enables expansion of the substrate treatment system without additionally providing the substrate transfer chamber 1. Moreover, by optimizing the shape of the connection between the plasma treatment apparatuses 231 and 232 (e.g., connecting the plasma treatment apparatuses 231 and 232 at an angle), the substrate treatment system can be expanded according to a vacant space in the installation place of the substrate treatment system, thereby increasing the degree of freedom of arrangement.

### Twelfth Embodiment

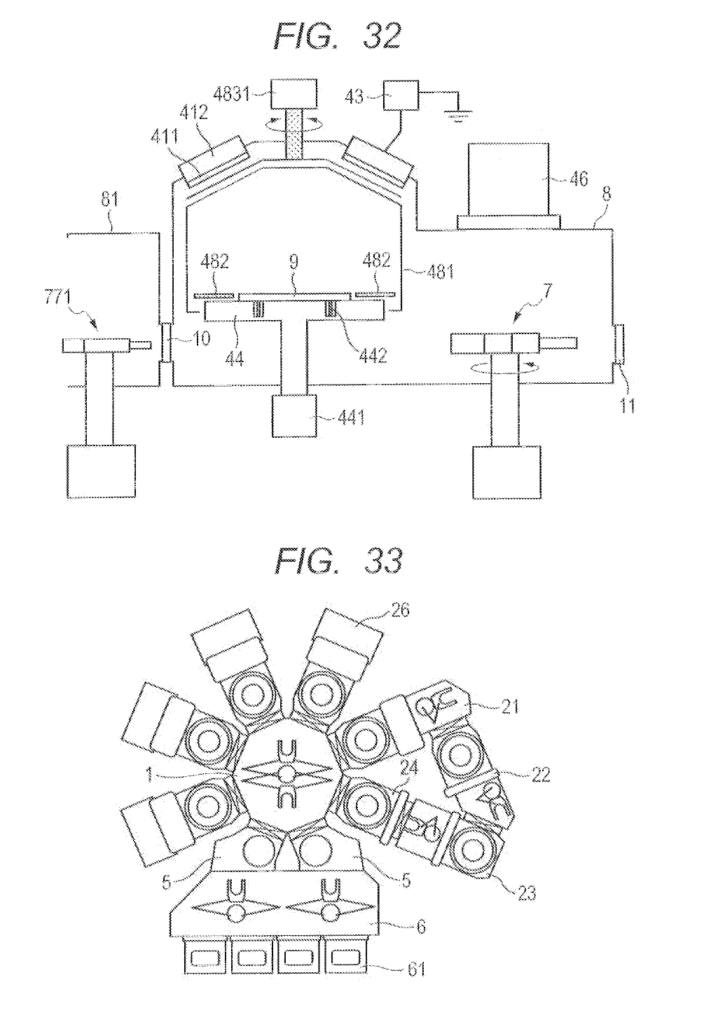

FIG. 33 is a schematic top view of a substrate treatment system according to this embodiment. A feature of this embodiment is that multiple plasma treatment apparatuses 21, 22, 23 and 24 according to the present invention are serially provided around a substrate transfer chamber 1, and the plasma treatment apparatuses 21 to 24 form an in-line system. Here, the in-line system is a system in which multiple treatment chambers are directly connected and a substrate is sequentially transferred to the treatment chambers for treatment. As the plasma treatment apparatuses 21 to 24, any of the plasma treatment apparatuses according to the embodiments described above may be used, or those with changes made thereto may be used.

By forming the in-line system around the substrate transfer chamber 1 as described above, the number of the plasma treatment apparatuses can be freely increased or reduced according to the treatment process of the substrate. Moreover, timing of transferring the substrate from a certain treatment apparatus to another treatment apparatus by using an arm inside the substrate transfer chamber 1 can be easily optimized as needed. For example, when substrate treatment in the other treatment chamber 23 takes time, treatment time in the treatment chamber 26 and a total treatment time in the plasma treatment apparatuses 21 to 24 are set approximately equal by forming the in-line system such as the plasma treatment apparatuses 21 to 24. Thus, throughput can be optimized.

### Thirteenth Embodiment

FIG. 34 is a schematic top view of a substrate treatment system according to this embodiment. A feature of this embodiment is that plasma treatment apparatuses 25 and 26 according to the present invention are serially provided around a substrate transfer chamber 1. Moreover, the substrate transfer chamber 1 is connected to the plasma treatment apparatus 25, while load lock chambers 5 are connected to the plasma treatment apparatus 26. As the plasma treatment apparatuses 25 and 26, any of the plasma treatment apparatuses according to the embodiments described above may be used, or those with changes made thereto may be used.

With such a configuration, the number of the plasma treatment apparatuses can be freely increased or reduced according to the treatment process of the substrate. Moreover, even when treatment time is approximately equal in the respective plasma treatment apparatuses, the substrate can be transferred between the plasma treatment apparatuses without through the substrate transfer chamber 1. Thus, additional plasma treatment apparatuses can be provided without lowering the throughput.

### Fourteenth Embodiment

The plasma treatment apparatus according to the present invention is not limited to the cluster-type apparatus as described in the above embodiments, but is also applicable to an in-line type apparatus. In a conventional in-line type apparatus, a substrate is placed on a belt or rail and transferred to an adjacent chamber. On the other hand, in the plasma treatment apparatus according to the present invention, the transfer robot 7 is shielded from plasma by the shield 481. Thus, generation of dust can be reduced.

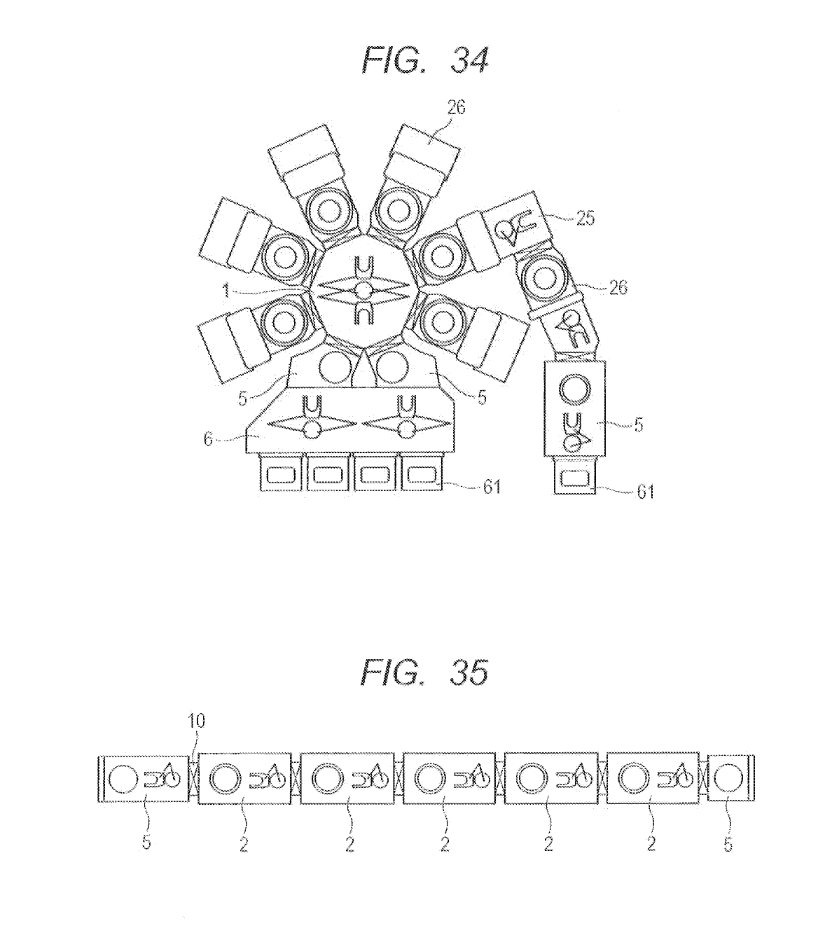

FIG. 35 is a schematic top view of a substrate treatment system according to this embodiment. The substrate treatment system according to this embodiment is the in-line type apparatus, in which multiple plasma treatment apparatuses 2 are connected in series and two load lock chambers 5 are connected to both ends thereof. A substrate is carried in from one of the load lock chambers 5 and is carried out from the other load lock chamber 5 after predetermined treatment is performed in each of the plasma treatment apparatuses 2.

As the plasma treatment apparatuses 2, any of the plasma treatment apparatuses according to the embodiments described above may be used, or those with changes made thereto may be used.

### Fifteenth Embodiment

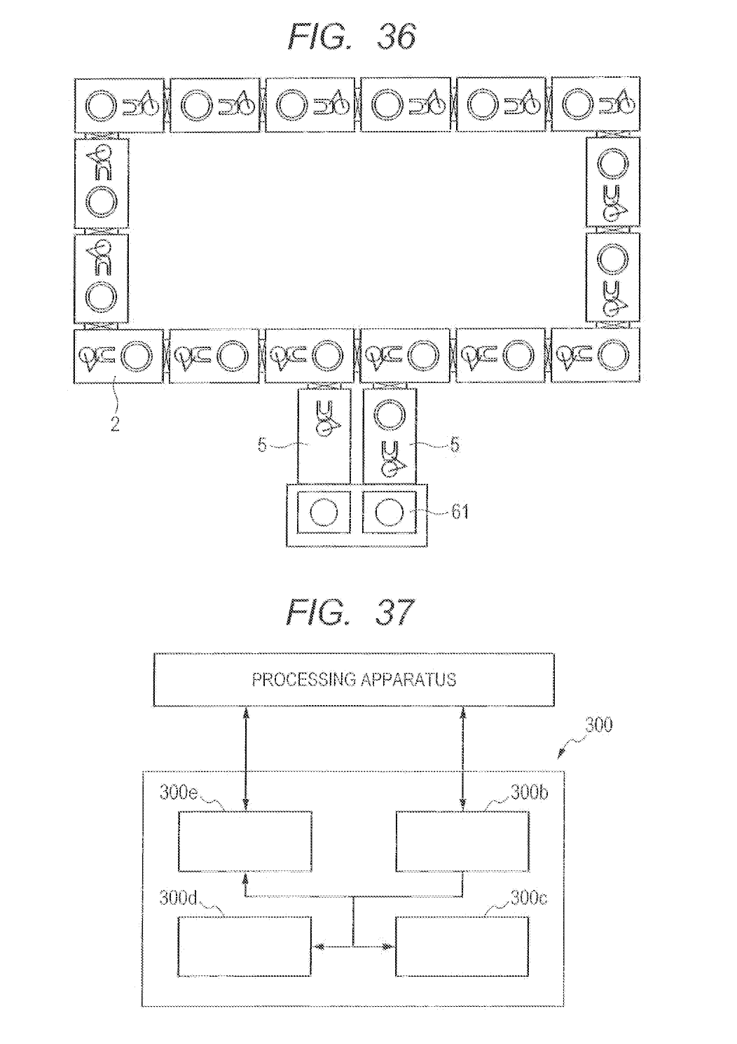

FIG. 36 is a schematic top view of a substrate treatment system according to this embodiment. The substrate treatment system according to this embodiment is configured by connecting multiple plasma treatment apparatuses 2 in a square pattern in the substrate treatment system according to the fourteenth embodiment shown in FIG. 35. A substrate is taken out from an external cassette 61, in which untreated substrates are housed, by an arm inside a load lock chamber 3 for installation, and is installed into each of the plasma treatment apparatuses 2. Then, the substrate is sequentially transferred to the respective plasma treatment apparatuses 2 for predetermined treatment. After all the treatment, the substrate is housed in the external cassette 61 for housing treated substrates by an arm inside a load lock chamber 5 for removal.

By connecting the plasma treatment apparatuses 2 while appropriately changing the positions of the gate valves 10 and 11 in each of the plasma treatment apparatuses 2 as described above, free arrangement can be realized.

The present invention is not limited to the embodiments described above, but can be appropriately changed without departing from the essence of the present invention. In the embodiments described above, the sputtering apparatus is used as an example of the plasma treatment apparatus according to the present invention. However, the plasma treatment apparatus according to the present invention is also applicable to other substrate treatment. For example, the plasma treatment apparatus according to the present invention may be used as an apparatus to perform substrate oxidation treatment, plasma etching treatment, plasma CVD, surface modification using plasma, and the like.

As described above, in the present invention, the substrate transfer means, such as the transfer robot, is provided in the first treatment chamber. The substrate transfer means is configured to perform at least one of installation of the substrate into the first treatment chamber and removal of the substrate from the first treatment chamber through a gate valve provided in the first treatment chamber, and to transfer the substrate inside the first treatment chamber. Therefore, even when the second treatment chamber is provided right next to the first treatment chamber through the gate valve, the substrate can be transferred between the first and second treatment chambers. Specifically, in the conventional technology, when a second treatment chamber is provided next to an already provided first treatment chamber, a transfer chamber needs to be provided between the first and second treatment chambers. Meanwhile, according to the present invention, the second treatment chamber, which enables the substrate to be transferred with the first treatment chamber, can be newly provided without providing the transfer chamber. Moreover, since the second treatment chamber can be provided right next to the first treatment chamber, an increase in installation area can be reduced. Furthermore, since the substrate is transferred to the next treatment chamber without through the transfer chamber, the substrate can be quickly transferred while suppressing throughput degradation.

Also, when additionally installing a new apparatus by tandem connection with one of the plasma treatment apparatuses which are cluster-type apparatuses, the new apparatus can be installed without minding a problem regarding substrate transfer to the additional apparatus, such as additionally presiding a mechanism for transferring the substrate to the additional apparatus.

Moreover, in a case of configuring an in-line type apparatus, when a second treatment chamber is provided right next to a first treatment chamber, there is no need to use a structure in which a rail is provided between the first and second treatment chambers and a carrier is transferred on the rail or a structure in which a substrate is transferred between the first and second treatment chambers by a belt. Thus, the in-line type apparatus can be configured while reducing complication of the apparatus.

Furthermore, in the treatment chamber, the shield is provided so as to shield the substrate transfer means from the plasma generated inside the treatment chamber. Thus, even when the substrate transfer means is provided in the plasma treatment apparatus in which the plasma is generated, plasma injection into the substrate transfer means can be reduced. Thus, the substrate transfer means can be protected from the plasma.

1. A substrate treatment system comprising:
a substrate transfer chamber for transferring a substrate to a chamber provided therearound;
a load lock chamber disposed on an atmosphere side of the substrate transfer chamber and hermetically connected to the substrate transfer chamber; and
a plurality of substrate treatment apparatuses provided around the substrate transfer chamber and hermetically connected to the substrate transfer chamber,
wherein at least one of the substrate treatment apparatuses is a plasma treatment apparatus, and the plasma treatment apparatus is further hermetically connected to a first substrate treatment apparatus different from the plurality of substrate treatment apparatuses,
wherein the plasma treatment apparatus includes:
a treatment chamber,
a first substrate holder for holding the substrate provided in the treatment chamber,
a plasma generation unit for forming plasma in the treatment chamber,
a first gate valve for carrying the substrate into and out of the treatment chamber from the substrate transfer chamber,
a second gate valve for carrying the substrate into and out of the first substrate treatment apparatus from the treatment chamber,
a substrate transfer unit, provided in the treatment chamber, for transferring the substrate inside the treatment chamber and performing at least one of installation and removal of the substrate into and from the treatment chamber through the second gate valve, and
a shield for surrounding the plasma formed by the plasma generation unit, the shield being provided so as to shield the substrate transfer unit from the plasma.

2. (canceled)

3. The substrate treatment system according to claim 1, wherein the substrate transfer unit includes:
a substrate holding part,
a first arm having one end connected to the substrate holding part,
a second arm having one end connected to another end of the first arm, and
an arm supporting part connected to another end of the second arm,
wherein the substrate holding part, the first arm and the second arm are respectively configured to be rotatable.

4. The substrate treatment system according to claim 3, further comprising a transfer control unit,
wherein the transfer control unit causes the plasma treatment apparatus to execute the steps of:
placing the substrate transfer unit at a retreat position shielded from the plasma by the shield before treatment of the substrate is started,
driving the arm supporting part, the first arm and the second arm to hold the substrate with the substrate holding part after the treatment of the substrate, and
driving the arm supporting part, the first arm and the second arm to remove the substrate held by the substrate holding part from the treatment chamber through the second gate valve.

5. The substrate treatment system according to claim 1, further comprising:
a gas introduction unit for introducing gas into the treatment chamber through a gas introduction part; and
an evacuation unit for evacuating the treatment chamber,
wherein the gas introduction part is provided in a substrate treatment space defined by the shield, and
wherein the evacuation unit is provided outside the substrate treatment space.

6-9. (canceled)

10. The substrate treatment system according to claim 1,
wherein the plasma treatment apparatus further includes a second substrate holder for holding a dummy substrate, and
wherein the substrate transfer unit is capable of transferring the dummy substrate to the first substrate holder from the second substrate holder.

11. The substrate treatment system according to claim 1,
wherein the plasma treatment apparatus is further hermetically connected to a second substrate treatment apparatus different from the plurality of substrate treatment apparatuses and the first substrate treatment apparatus,
wherein the plasma treatment apparatus further includes a third gate valve for carrying the substrate into and out of the second substrate treatment apparatus from the treatment chamber, and
wherein the substrate transfer unit performs at least one of installation and removal of the substrate into and from the treatment chamber through the third gate valve.

12. The substrate treatment system according to claim 11, wherein the third gate valve is provided at a position higher from a bottom surface of the treatment chamber than the second gate valve.

13. The substrate treatment system according to claim 5, further comprising a shield part for shielding the gas introduction part from the plasma.
